(19) United States
(12) Patent Application Publication
(10) Pub. No.: US 2025/0151269 A1
(43) Pub. Date: May 8, 2025

(54) INTEGRATED CIRCUIT INCLUDING A MEMORY CELL AND CORRESPONDING MANUFACTURING METHOD

(71) Applicant: STMicroelectronics International N.V., Geneva (CH)

(72) Inventors: Madjid AKBAL, Trets (FR); Franck MELUL, Aubagne (FR); Arnaud REGNIER, Les Taillades (FR); Francesco LA ROSA, Rousset (FR)

(73) Assignee: STMicroelectronics International N.V., Geneva (CH)

(21) Appl. No.: 18/933,452

(22) Filed: Oct. 31, 2024

(30) Foreign Application Priority Data
Nov. 2, 2023 (FR) 2311932

(51) Int. Cl. H10B 41/30; H01L 29/423; H10B 41/10

(52) U.S. Cl. CPC H10B 41/30; H10D 30/6892; H10D 30/6894; H10B 41/10

(57) ABSTRACT

An integrated circuit includes a semiconductor substrate and at least one memory cell provided with a vertical gate selection transistor buried in the substrate and a floating gate state transistor. The floating gate state transistor covers a first active region and a second active region of the substrate delimited by lateral isolation regions. The memory cell includes a lateral isolation region thickness (in breadth) dimension between a sidewall of the vertical gate of the buried transistor and the second active region.

### PRIORITY CLAIM

This application claims the priority benefit of French Application for U.S. Pat. No. 2,311,932 filed on Nov. 2, 2023, the content of which is hereby incorporated by reference in its entirety to the maximum extent allowable by law.

### TECHNICAL FIELD

Embodiments and implementations relate to non-volatile memory integrated circuits, particularly memories capable of implementing a programming and an erasure with a granularity of one bit.

### BACKGROUND

Non-volatile memories that can be programmed and erased with a granularity of one bit have been proposed in a technology including memory cells provided with a vertical gate selection transistor buried in a semiconductor substrate and with a floating gate state transistor.

In this type of architecture, there is an interface between the gate of the selection transistor and an active region supporting erase conditions, aiming to obtain, for example, a Fowler-Nordheim effect with the floating gate of the state transistor. In particular, this is the case in a so-called “split voltage” technique.

Indeed, in the split voltage technique, opposite sign potentials are typically generated on either side of the floating gate, for example substantially-8 V in the control gate of the state transistor and substantially +8 V in the active region, whereas the gate of the selection transistor is typically at 0 V.

In conditions of this type, the interface between the gate of the selection transistor and the active region, which typically includes a gate dielectric layer, is subjected to a voltage of 8 V.

Thus, the interface must on the one hand be able to withstand a stress of 8 V at each erasure cycle throughout the entire service life of the product.

On the other hand, a space charge area may form at the interface between the gate of the selection transistor and the active region, which results in a loss in efficiency of the erasure.

Increasing the thickness of the gate dielectric layer at the interface between the gate of the selection transistor and the active region makes it possible to increase the voltage resistance and to limit the loss in efficiency of the erase operations.

However, it is advantageous to benefit from a co-integrated manufacturing of capacitive elements (capacitors) simultaneously with the manufacturing of buried vertical gates.

Yet, increasing the thickness of the gate dielectric layer of the selection transistor, results in, in the event of co-integration, an increase in the thickness of the dielectric layer of the capacitive interface and therefore a degradation of the performances of the capacitor (lower capacitive value).

Providing a dissociation of two dielectric layers in the vertical gate structures, in order to obtain two different thicknesses, results in an increase in the manufacturing cost and a loss of the advantage of the co-integration.

Thus, there is a need to remedy the aforementioned drawbacks, that is to say a need to increase the voltage resistance of the buried vertical gate and to improve the efficiency of the erase operations of the memory cell, without resulting in losses of performance of any co-integrated capacitive element, or increase in production costs.

### SUMMARY

Embodiments and implementations defined hereinafter propose a production of memory cell wherein the thickness of the dielectric interface between the vertical gate and the second active region is increased, without increasing the thickness of the gate dielectric of the dielectric interface of the co-integrated capacitive element, and without adversely affecting the co-integration or resulting in additional costs.

Thus, according to one aspect, an integrated circuit is proposed including a semiconductor substrate and at least one memory cell provided with a vertical gate selection transistor buried in the substrate, and with a floating gate state transistor covering a first active region and a second active region of the substrate delimited by lateral isolation regions; wherein the memory cell includes a lateral isolation region thickness between a sidewall of the vertical gate of the buried transistor and the second active region.

For example, the lateral isolation regions are of the shallow trench isolation type.

This aspect offers a solution that is free and compatible with almost all manufacturing methods given that almost all technologies provide lateral isolation regions.

According to one embodiment, the vertical gate of the selection transistor includes a dielectric shell on the sidewalls and the bottom of a trench in the substrate filled by a conductive region, said lateral isolation region thickness between the sidewall of the vertical gate and the second active region being at least 5 times greater than the thickness of the dielectric shell.

According to one embodiment, the integrated circuit further includes a capacitive element provided with a vertical conductive electrode buried in the substrate having the same structure and the same composition as the vertical gate of the selection transistor.

According to one embodiment, the second active region includes an implantation of dopants of the type opposite to that of the substrate, occupying a volume located under the floating gate of the state transistor.

It will be noted that the presence of the thickness of the lateral isolation region between the sidewall of the vertical gate of the buried transistor and the second active region offers further to the aforementioned advantages, an additional robustness in the alignment of the implantation in the second active region.

According to one embodiment, the integrated circuit further includes a write circuit configured to generate programming and erase conditions, respectively adjusted to result in charge transfers of a first sign between the floating gate and the first active region, and charge transfers of a second sign between the floating gate and the second active region.

According to another aspect, a method for manufacturing at least one memory cell of an integrated circuit comprises: forming lateral isolation regions in a semiconductor substrate that delimit a first active region and a second active region; forming a vertical gate selection transistor buried in the substrate and positioned so that a lateral isolation region thickness is located between a sidewall of the vertical gate and the second active region; and forming a floating gate state transistor covering the first active region and the second active region.

According to one implementation, forming the vertical gate of the selection transistor includes: etching a trench in the substrate; forming a dielectric shell on the sidewalls and the bottom of the trench; and forming a conductive region filling the remainder of the trench. The etching of the trench is positioned opposite the lateral isolation region so as to conserve after the etching said lateral isolation region thickness between the sidewall of the vertical gate and the second active region, at least 5 times greater than the thickness of the dielectric shell.

According to one implementation, the formation of the vertical gate of the selection transistor is carried out jointly with a formation of a vertical conductive electrode buried in the substrate of a capacitive element. Consequently, the electrode particularly has the same structure and the same composition as the vertical gate of the selection transistor.

According to one implementation, the method further includes an implantation, in the second active region, of dopants of the type opposite to that of the substrate occupying a volume located under the future floating gate.

According to one implementation, the method further includes forming a write circuit configured to generate programming and erase conditions, respectively adjusted to result in charge transfers of a first sign between the floating gate and the first active region, and charge transfers of a second sign between the floating gate and the second active region.

### BRIEF DESCRIPTION OF THE DRAWINGS

Other advantages and features of the invention will become apparent upon examining the detailed description of non-limiting embodiments and implementations, and from the accompanying drawings, wherein:

FIGS. 1A, 1B and 1C illustrate a first example of memory cell;

FIGS. 2A and 2B illustrate a second example of the memory cell;

FIGS. 3 to 8 illustrate steps of a method for manufacturing the memory cell, advantageously with a co-integrated manufacturing of a capacitive element; and

FIG. 9 is a table of values illustrating an example of voltage conditions on the control gate, on the drain, on the vertical gate of the selection transistor and on the isolation source plane, making it possible to implement programming and erase operations in the memory cell.

### DETAILED DESCRIPTION

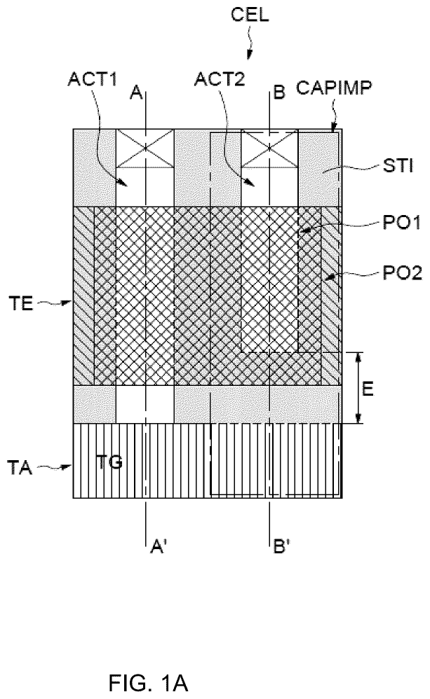

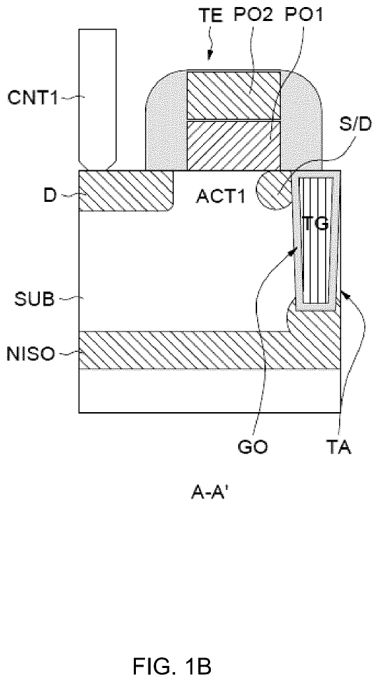

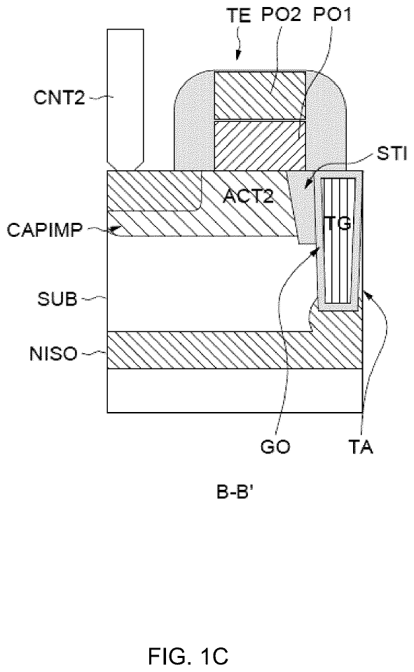

FIGS. 1A, 1B and 1C illustrate a first example of memory cell CEL, produced in and on a semiconductor substrate SUB of an integrated circuit.

FIG. 1A illustrates a top view of the cell CEL, the elements of which are shown transparently.

FIG. 1B illustrates a sectional view of the cell CEL, in the plane AA′ of FIG. 1A.

FIG. 1C illustrates a sectional view of the cell CEL, in the plane BB′ of FIG. 1A.

The cell CEL is provided with a vertical gate TG selection transistor TA buried in the substrate, and with a state transistor TE. The state transistor TE includes a floating gate PO1 capable of storing charges in a non-volatile manner, and a control gate PO2 capable of receiving control potentials.

The vertical gate TG structure buried in the substrate includes a dielectric shell GO on the sidewalls and the bottom of a trench in the substrate SUB, the remainder of the volume of the trench being filled by a gate conductive region P0, for example made of polycrystalline silicon.

The stacked structure of the floating PO1 and control gates PO2 of the state transistor TE covers a first active region ACT1 and a second active region ACT2 of the substrate, delimited by lateral isolation regions STI, typically shallow isolation trenches.

In the first active region ACT1, the state transistor TE and the selection transistor TA are coupled in series, with a drain region D of the state transistor, typically accessible via a bitline and the contact CNT1, a conduction region S/D (used as source of the state transistor TE and as drain of the selection transistor TA), up to a source region of the selection transistor TA located in a NISO well implanted in depth in the substrate SUB.

The second active region ACT2 includes an implantation of dopants CAPIMP of the type opposite to that of the substrate, occupying a volume located under the floating gate of the state transistor TE.

The implanted region CAPIMP is located at the surface of the substrate SUB, and extends deeper than the drain D and conduction S/D implanted regions, but shallower than the lateral isolation regions STI.

A contact CNT2 makes it possible to electrically connect the implanted region CAPIMP of the second active region ACT2.

The sectional plane AA′ passes longitudinally through the first active region ACT1, whereas the sectional plane BB′ passes longitudinally through the second active region ACT2.

In the first example of memory cell CEL, the first active region ACT1 and the second active region ACT2 extend parallel in length in a first direction, and are passed through by the stack of gates of the state transistor TE and by the buried vertical gate TG that extend parallel in a second direction perpendicular to the first direction.

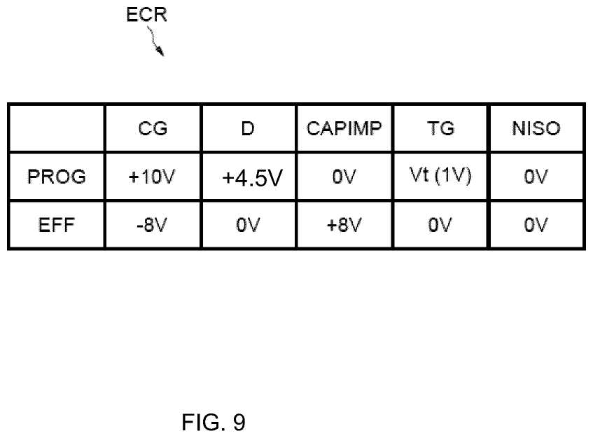

The first active region ACT1 is provided to implement write operations of the programming type and readouts of the data contained in the memory cell CEL, whereas the second active region ACT2 is provided to implement write operations of the data erase type. Reference is made with regards to the write operations ECR, in FIG. 9.

FIG. 9 is a table of values illustrating an example of voltage conditions on the control gate CG (PO2), on the drain D/CAPIMP (also biasing the implanted region CAPIMP in the second active region ACT2), on the vertical gate of the selection transistor TG and on the NISO source plane, making it possible to implement programming PROG and erase EFF operations in the memory cell CEL.

The various write voltages may be generated and distributed by conventional write circuitry, which will not be described in detail here.

The programming conditions PROG include a biasing of the control gate at +10 V, of the drain D at +4.5 V, of the implanted region CAPIMP in the second active region ACT2 at 0 V of the vertical gate at a voltage Vt sufficient to result in a conduction channel, for example 1 V, and of the source plan S at 0 V.

These programming conditions PROG make it possible to form a conduction channel region, from the drain D to the NISO source plane, and to generate an ionizing phenomenon by impact on the source S/D side of the state transistor TE, in order to result in an injection of hot carriers (of negative sign) in the floating gate from the channel on the source S/D side.

The erase conditions EFF, of the split voltage type include a biasing of the control gate at −8 V, of the drain D at 0 V, and of the implanted region CAPIMP in the second active region ACT2 at +8 V, of the vertical gate at a blocking voltage at 0 V and of the source plane S at 0 V.

These erase conditions EFF make it possible to generate a charge (of negative sign) transfer by Fowler-Nordheim effect from the floating gate PO1 to the second active region ACT2 by means of the implanted region CAPIMP.

The erase conditions EFF may also make it possible to generate a positive sign charge transfer (for example also by Fowler-Nordheim effect) in the floating gate PO1, by means of the implanted region CAPIMP.

These write conditions, and particularly the erasure EFF, offer good performances, a granularity of one bit, and little disturbance in the neighboring cells.

Furthermore, and with reference again to FIGS. 1A, 1B and 1C, advantageously in relation to the write conditions described above, a lateral isolation region STI thickness (in breadth) E dimension between a sidewall of the vertical gate TG of the buried transistor and the second active region ACT2 is conserved after the etching of the trench TG in the memory cell CEL.

Indeed, this makes it possible on the one hand to protect against a stress of the gate dielectric GO of the selection transistor TA subjected to a voltage of 8 V for the erase operations.

And on the other hand, this makes it further possible to avoid a formation of an inversion area (otherwise known as space charge area) along the vertical gate buried at the interface with the second active region ACT2 for the erase operations, which causes a loss of efficiency of the erasure.

According to one order of magnitude, the lateral isolation region STI thickness (in breadth) E dimension between the sidewall of the vertical gate and the second active region ACT2 is at least 5 times greater than the thickness of the dielectric shell GO. Indeed, according to the technological manufacturing limits (or node), said thickness (in breadth) E dimension could be in the order of 5 to 25 times greater than the thickness of the dielectric shell GO.

For example, the thickness (in breadth) E dimension of STI conserved may have a size between 0.03 μm and 0.25 μm, for example 0.08 μm, whereas the gate dielectric layer may have a thickness of a few nanometers, for example from 3 nm to 10 nm.

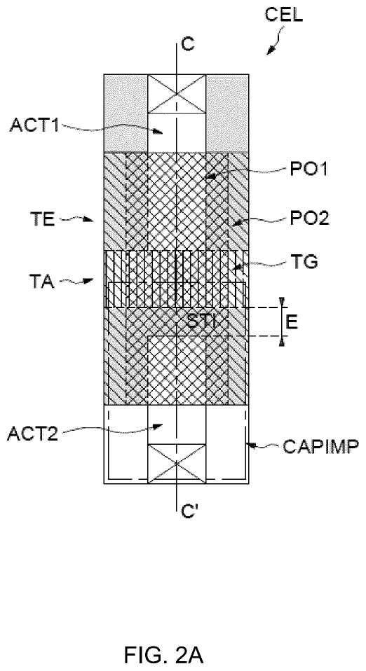

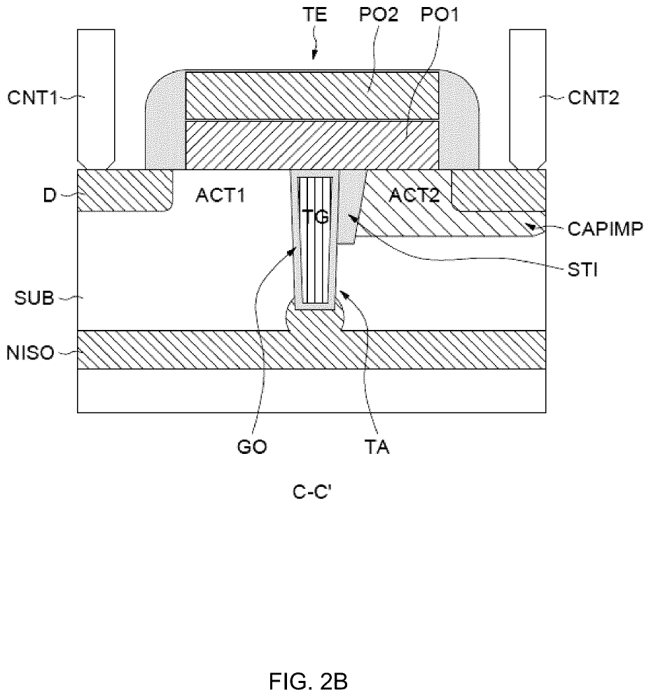

FIGS. 2A and 2B illustrate a second example of the memory cell CEL, which differs from the first from an architectural point of view (that is to say in the arrangements of the elements produced), and not from a functional point of view.

FIG. 2A illustrates a top view of the cell CEL, the elements of which are shown transparently.

FIG. 2B illustrates a sectional view of the cell CEL, in the plane CC′ of FIG. 2A.

The second example of the memory cell CEL is an architectural alternative in relation to the first example of the memory cell CEL, where only the layout of the elements of the memory cell has changed.

In the second example of the memory cell CEL, the first active region ACT1 and the second active region ACT2 are aligned in length in the first direction, on either side of the vertical gate TG that extends in the second direction perpendicular to the first.

The stack of gates of the state transistor TE covers the vertical gate as well as the first active region ACT1 and the second active region ACT2 of each side of the selection transistor TA in the first direction.

The sectional plane CC′ passes longitudinally through the first active region ACT1, passes laterally through the vertical gate TG, and passes longitudinally through the second active region ACT2.

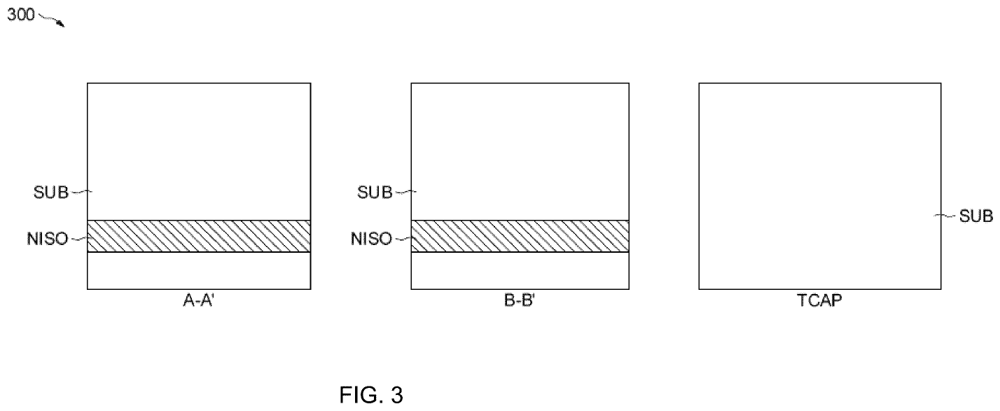

The elements of the memory cell CEL according to the two examples are the same, and bear the same references. The description made previously in relation to FIGS. 1A, 1B and 1C applies to the memory cell CEL of FIGS. 2A and 2B except for the layout described above. FIGS. 3 to 8 illustrate steps of a method for manufacturing the memory cell CEL, advantageously with a co-integrated manufacturing of a capacitive element TCAP.

The sectional views in the planes AA′ and BB′ corresponding to the planes in FIGS. 1B and 1C are shown for the manufacturing of the memory cell CEL in the layout of the first example, and as well as a corresponding sectional view for the capacitive element TCAP.

FIG. 3 illustrates a step 300 wherein the NISO region is implanted in depth in the substrate SUB in the region of the substrate receiving the memory cell CEL.

The substrate SUB is for example conventionally P-type doped silicon, the NISO layer implanted in depth being N-type doped.

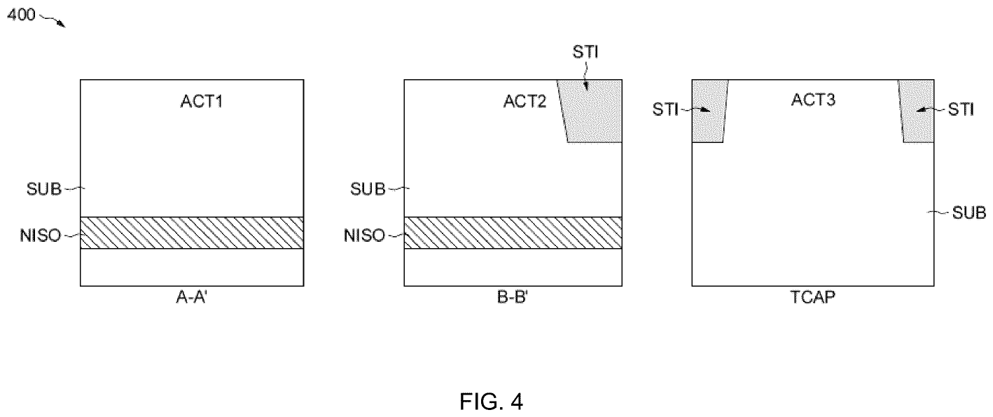

FIG. 4 illustrates a step 400 wherein the lateral isolation regions STI are formed, for example according to the shallow trench isolation technique wherein a shallow trench is opened in the substrate that is filled with a dielectric volume such as silicon oxide.

The lateral isolation regions STI make it possible to define between them active regions ACT1, ACT2, ACT3, at the surface of the substrate SUB.

In particular, it will be noted that a lateral isolation region STI passing through the sectional plane BB′ of the memory cell is provided at this step 400.

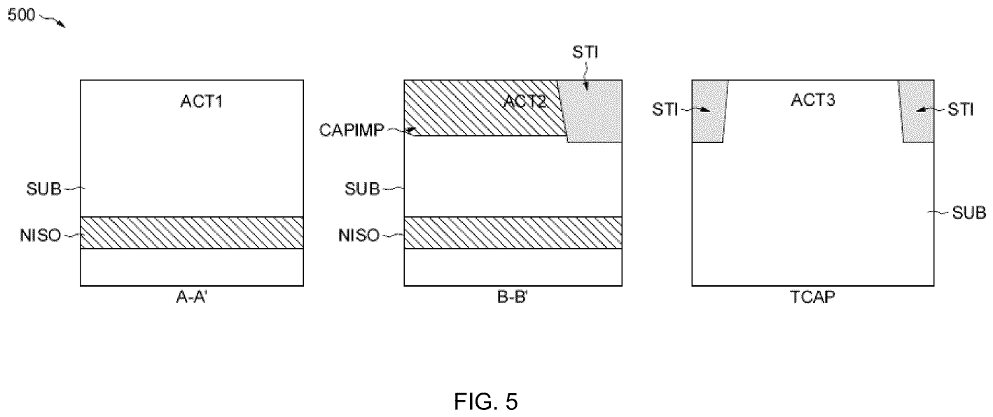

FIG. 5 illustrates a step 500 of implanting, in the second active region ACT2, dopants of the type opposite to that of the substrate SUB (that is to say an implantation of N-type dopants) occupying the entire extent of the second active region ACT2 at the surface, up to a depth lower, but of comparable magnitude, than the depth of the lateral isolation regions STI.

The presence of the lateral isolation region STI in the plane BB′ of the second active region ACT2 provides an additional robustness in the alignment of the implantation CAPIMP.

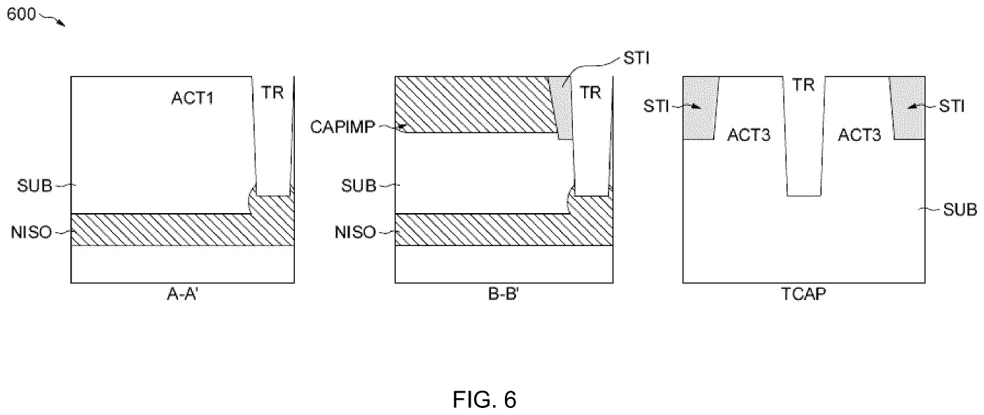

FIG. 6 illustrates a step 600 of etching trenches TR that will receive the vertical gate structure of the selection transistor TA of the memory cell CEL and the vertical electrode structure of the capacitive element TCAP.

In the plane BB′, the etching 600 of the trench TR is positioned opposite the lateral isolation region STI so as to conserve after the etching 600 a thickness (in breadth) E dimension of the lateral isolation region STI between the sidewall of the future vertical gate and the second active region ACT2.

The thickness (in breadth) E dimension may be configured so as to be at least 5 times greater than the thickness of the gate dielectric layer GO formed in the following step 700.

The thickness (in breadth) E dimension of the remaining lateral isolation region may be substantially 0.08 μm, for example between 0.03 μm and 0.25 μm.

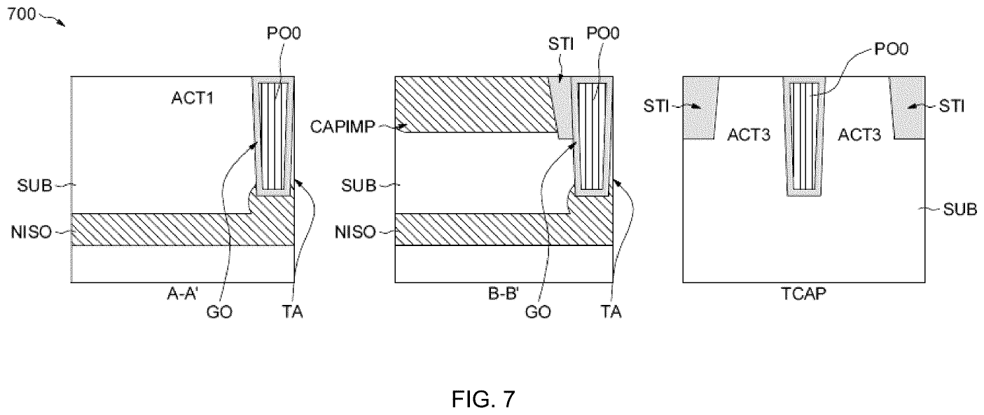

FIG. 7 illustrates a step 700 wherein a dielectric shell GO is formed on the sidewalls and the bottom of the trench TR and a formation of a conductive region PO0 filling the remainder of the trench TR.

The dielectric shell GO, for example made of silicon oxide, has a thickness of the logic transistor gate dielectric type, typically less than 10 nm, for example from 3 to 10 nm.

This order of magnitude of the thickness of the dielectric shell GO advantageously makes it possible to benefit from a high capacitive value in the production of the capacitor TCAP.

Indeed, the capacitive interface of the capacitor TCAP is located between the conductive region PO0 filling the trench and the active region ACT3 of the substrate, that is to say the dielectric layer GO.

The conductive region PO0 is, for example, formed by excessively filling with polycrystalline silicon then chemical mechanical planarization until the front face of the substrate SUB is uncovered.

Thus, in the first active region ACT1 of the memory cell and in the third active region ACT3 receiving the capacitor TCAP, the thickness of the dielectric interface between the gate conductive region PO0 and the substrate SUB is the thickness of the gate dielectric GO.

This is particularly advantageous for controlling the selection transistor TA in the first active region ACT1, and the capacitive value of the capacitive element TCAP.

In the second active region ACT2 of the memory cell CEL, the thickness of the dielectric interface between the gate conductive region PO0 and the substrate SUB includes the accumulation of the gate dielectric layer GO and of the remaining thickness (in breadth) E dimension of the lateral isolation region STI, of the front face of the substrate up to a depth going beyond the depth of the implanted region CAPIMP (it will be noted that the implanted region CAPIMP will support the erasure voltage of 8 V).

The remainder of the dielectric interface between the gate conductive region PO0 and the substrate SUB, that is to say between the bottom of the lateral isolation region STI and the NISO well implanted in depth, has the thickness of the gate dielectric layer GO (in the erase conditions, the substrate SUB facing this thickness GO is at a substantially zero potential).

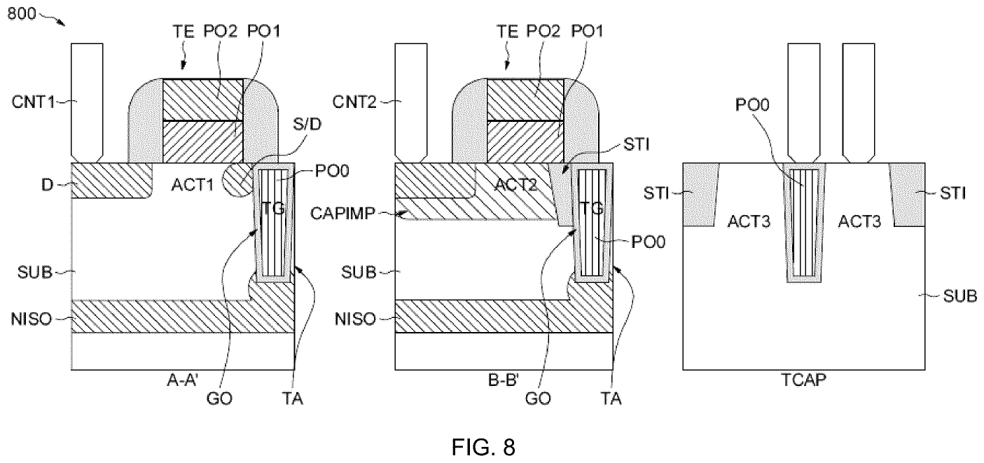

FIG. 8 illustrates a formation 800 of the stack of the floating gate PO0 and of the control gate PO2, conventionally, in the portion receiving the memory cell CEL.

In summary, a memory cell is formed wherein the thickness of the dielectric interface between the vertical gate and the second active region is increased, without increasing the thickness of the gate dielectric of the dielectric interface of the co-integrated capacitive element, and without resulting in a dedicated step or additional cost.

The thicker dielectric interface makes better isolation possible between the implanted region CAPIMP in the second active region ACT2, and the vertical gate of the selection transistor TA.

The better isolation between the second active region ACT2 (CAPIMP) and the vertical gate of the selection transistor TA, makes it possible to have a better efficiency of the erasure, due to the absence of the space charge area between the implanted region CAPIMP and the dielectric interface; and also a potentially greater service life due to a better reliability of the dielectric thickness at the erasure area.

Furthermore, the possibility of co-integrating the two different dielectric interface thicknesses makes it possible on the one hand to not increase the manufacturing cost in terms of additional masks and steps; and at the same time also makes it possible to not degrade the capacitive value of the capacitor, so that the costs due to the surface footprint of the capacitor also do not increase.

1. An integrated circuit, comprising:
a semiconductor substrate; and
a memory cell provided with a vertical gate selection transistor buried in the substrate, and with a floating gate state transistor covering a first active region and a second active region of the substrate delimited by lateral isolation regions;
wherein the memory cell includes a lateral isolation region thickness between a sidewall of the vertical gate of the buried transistor and the second active region.

2. The integrated circuit according to claim 1, wherein the vertical gate of the selection transistor includes a dielectric shell on the sidewalls and the bottom of a trench in the substrate filled by a conductive region, said lateral isolation region thickness between the sidewall of the vertical gate and the second active region being at least 5 times greater than a thickness of the dielectric shell.

3. The integrated circuit according to claim 1, further including a capacitive element provided with a vertical conductive electrode buried in the substrate having a same structure and a same composition as the vertical gate of the selection transistor.

4. The integrated circuit according to claim 1, wherein the second active region includes an implantation of dopants of the type opposite to that of the substrate, said implantation occupying a volume located under the floating gate of the state transistor.

5. The integrated circuit according to claim 1, further including write circuitry configured to generate programming and erase conditions, respectively adjusted to result in charge transfers of a first sign between the floating gate and the first active region, and charge transfers of a second sign between the floating gate and the second active region.

6. A method for manufacturing a memory cell of an integrated circuit comprising:
forming lateral isolation regions in a semiconductor substrate which delimit a first active region and a second active region;
forming a vertical gate selection transistor buried in the substrate, positioned so that a lateral isolation region thickness is located between a sidewall of the vertical gate and the second active region; and
forming a floating gate state transistor covering the first active region and the second active region.

7. The method according to claim 6, wherein forming the vertical gate of the selection transistor comprises: etching a trench in the substrate; forming a dielectric shell on the sidewalls and the bottom of the trench; and forming a conductive region filling the remainder of the trench; wherein the etching of the trench is positioned opposite the lateral isolation region so as to conserve after the etching said lateral isolation region thickness between the sidewall of the vertical gate and the second active region that is at least 5 times greater than the thickness of the dielectric shell.

8. The method according to claim 6, wherein forming the vertical gate of the selection transistor is carried out jointly with forming a vertical conductive electrode buried in the substrate of a capacitive element.

9. The method according to claim 6, further including implanting, in the second active region, dopants of the type opposite to that of the substrate occupying a volume located under a location for the floating gate.

10. The method according to claim 6, further including forming write circuitry configured to generate programming and erase conditions, respectively adjusted to result in charge transfers of a first sign between the floating gate and the first active region, and charge transfers of a second sign between the floating gate and the second active region.
